(19) United States
(12) Patent Application Publication
(10) Pub. No.: US 2012/0048361 A1
(43) Pub. Date: Mar. 1, 2012

(54) THIN FILM SOLAR CELL HAVING ADJUSTABLE OR DESIGNABLE PATTERNS

(75) Inventors: YEE SHYI CHANG, TAIPEI (TW); YUHAI LIU, TAIPEI (TW); CHI-JEN LIU, TAIPEI (TW)

(73) Assignee: AN CHING NEW ENERGY MACHINERY & EQUIPMENT CO., LTD., Taipei (TW)

(21) Appl. No.: 13/017,404

(22) Filed: Jan. 31, 2011

(30) Foreign Application Priority Data
Aug. 24, 2010 (TW) 99128295

(51) Int. Cl. H01L 31/0216; H01L 31/0236

(52) U.S. Cl. 136/256

(57) ABSTRACT

A thin film solar cell having adjustable or designable patterns, comprising:

a transparent substrate; an upper electrode layer; a photovoltaic layer; and a lower electrode layer. Said upper electrode layer is disposed on said transparent substrate, and said upper electrode layer is a transparent electrode. Said photovoltaic layer is disposed on said upper electrode layer; and said lower electrode layer is disposed on said photovoltaic layer, and said lower electrode layer is provided with said adjustable or designable patterns, so as to achieve purpose of esthetically pleasing, sales promotion, and theft prevention.

### BACKGROUND OF THE INVENTION

1. Field of the Invention

The present invention relates to a solar cell, and in particular to a thin film solar cell having esthetical appearance, sales promotion, and theft prevention functions by means of its adjustable or designable patterns.

2. The Prior Arts

Along with the global concern about environment protection, and worldwide acceptance and implementation of the concept of “energy conservation and carbon reduction”, therefore, the development and utilization of regenerated energy resources has been the keypoint of development for various countries of the world. Among the regenerated energy resources, solar energy and solar cell capable of converting sunlight into electrical energy are of the most promising energy industry, since sunlight is available all over the world, and it would not create pollution to the Earth like other energy resources (such as nuclear energy, petrochemical energy).

In case that the solar cell is provided with a large light irradiating area, then it can produce relatively large amount of electrical energy for use by various devices. Therefore, quite a lot of manufacturers hope to combine the concept of “green energy building” with the solar cell, namely, putting solar cell in a building, where it is most exposed and irradiated by sunlight, as such, the energy generated by solar cell can be used to compensate for the electrical energy consumed by the building.

In this respect, presently, the design and performance of the solar cell is still not perfect, and it has much room for improvement.

### SUMMARY OF THE INVENTION

In view of the problems and shortcomings of the prior art, the present invention provides a thin film solar cell having adjustable or designable patterns, which is able to produce esthetical appearance, sales promotion, and theft prevention effects.

The present invention provides a thin film solar cell having adjustable and designable patterns, comprising: a transparent substrate, an upper electrode layer, a photovoltaic layer, and a lower electrode layer. The upper electrode layer is provided on the transparent substrate, wherein, the upper electrode layer is a transparent electrode, the photovoltaic layer is provided on the upper electrode layer. The lower electrode layer is provided on the photovoltaic layer, wherein, the lower electrode layer is provided with adjustable or designable patterns.

According to an embodiment of the present invention, the lower electrode layer includes a conductive layer and a thin film pattern layer, wherein, the thin film pattern layer is provided with patterns which can be adjusted or designed by the designer, and the conductive layer is disposed between the photovoltaic layer and the thin film pattern layer.

According to another embodiment of the present invention, the conductive layer is a transparent conductive layer.

According to yet another embodiment of the present invention, the thin film pattern layer can be classified into a plurality of color regions according to the patterns, and color regions of the same color are applied with metal of the same color.

According to a further embodiment of the present invention, the lower electrode layer can be classified into a plurality of color regions according to the patterns, and color regions of the same color are applied with metal of the same color.

According to another embodiment of the present invention, the patterns can be trademark patterns, logo patterns, or company names.

According to yet another embodiment of the present invention, the thin film solar cell further includes a temperature dependent optical layer, disposed between the photovoltaic layer and the lower electrode layer. The transmittance of the temperature dependent optical layer to the infrared light can be varied according to temperature, and when its temperature increases to a specific range, its transmittance to the infrared light is reduced.

According to a further embodiment of the present invention, the temperature dependent optical layer is made of vanadium dioxide.

According to another embodiment of the present invention, the photovoltaic layer includes an N-type semiconductor layer and a P-type semiconductor layer, and the N-type semiconductor layer and the P-type semiconductor layer are disposed sequentially between the upper electrode layer and the lower electrode layer.

According to the description mentioned above, in an embodiment of the present invention, in the lower electrode layer is provided with adjustable or designable patterns, such that the operations of the photovoltaic layer can be sustained by means of the sunlight incident through the transparent substrate, also users may view and appreciate the various patterns in the thin film solar cell. In this respect, product identification codes can be placed into the lower electrode layer of the thin film solar cell, so as to realize the objective of esthetic appearance, brand identification, sales promotion, and theft prevention. Moreover, in another embodiment of the present invention, a temperature dependent optical layer can be provided, so that the transmittance of the thin film solar cell to the infrared light in the sunlight can be adjusted depending on the temperature, so as to control the lighting and temperature of a building, hereby lowering the air conditioner utilization rate, and reducing expense on electricity.

Moreover, in addition to being applicable to window or roof of a building for esthetics and sales promotion purpose, the thin film solar cell having adjustable or designable patterns can also be applicable to a plant or flower cultivating industry requiring much more green light or mixture of blue light and green light. In order words, the intelligent thin film solar cell of an embodiment of the present invention is able to make great contributions to various Industries.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a cross section view of thin film solar cell having adjustable or designable patterns according to an embodiment of the present invention; and

FIG. 2 is a cross section view of thin film solar cell having adjustable or designable patterns at according to another embodiment of the present invention.

### DETAILED DESCRIPTION OF THE PREFERRED EMBODIMENT

The purpose, construction, features, functions and advantages of the present invention can be appreciated and understood more thoroughly through the following detailed description with reference to the attached drawings. And, in the following, various embodiments are described in explaining the technical characteristics of the present invention.

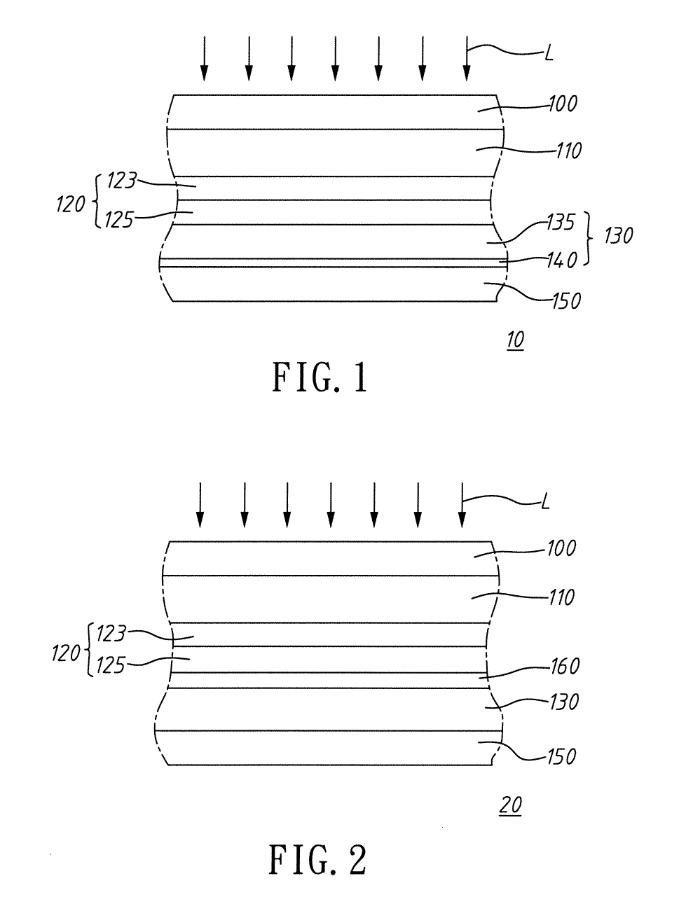

Refer to FIG. 1 for a cross section view of thin film solar cell having adjustable or designable patterns according to an embodiment of the present invention. As shown in FIG. 1, the thin film solar cell 10 includes a transparent substrate 100, an upper electrode layer 110, a photovoltaic layer 120, a lower electrode layer 130, and a transparent substrate 150.

The transparent substrate 100 is a glass substrate, such that light L incident into the thin film solar cell 10 through the transparent substrate 100, as shown in FIG. 1. The upper electrode layer 110 is disposed on the transparent substrate 100, in the present embodiment, the upper electrode layer 110 is the electrode layer close to direction of incident light L; the upper electrode layer 110 is a transparent electrode, and it is made of transparent conductive oxide, such as indium tin oxide (ITO), Al doped ZnO (AZO), indium zinc oxide (IZO), ZnO, or other transparent conductive materials.

Refer again to FIG. 1, wherein, the photovoltaic layer 120 is disposed on the upper electrode layer 110. In the present embodiment, in case that the photovoltaic layer 120 of the thin film solar cell 10 is of a single junction structure, then the photovoltaic layer 120 may includes an N-type semiconductor layer 123 and a P-type semiconductor layer 125 disposed sequentially between the upper electrode layer 110 and the lower electrode layer 140. To be more specific, N-type semiconductor layer 123 is made of amorphous silicon or microcrystalline silicon, and it is doped with materials selected from Group VA of the periodic table, such as N, P, As, Sb, or Bi, etc. In addition, P-type semiconductor layer 125 is made of amorphous silicon or microcrystalline silicon, and it is doped with materials selected from Group IIIA of periodic table, such as B, Al, Ga, In or Tl, etc.

The descriptions mentioned above is by way of example only, however, the present invention is not limited to this. In other alternative embodiments, the photovoltaic layer 120 of the thin film solar cell 10 can be of a double junction or triple junction structure. In other words, the thin film solar cell 10 of the present embodiment can be an amorphous silicon thin film solar cell, a microcrystalline silicon thin film solar cell, a tandem thin film solar cell, or a triple silicon thin film solar cell. It is worth mentioning that, in FIG. 1, the photovoltaic layer 120 may also includes a high temperature intrinsic amorphous silicon layer (not shown), which can be disposed between the N-type semiconductor layer 123 and the P-type semiconductor layer 125, so as to enhance the photoelectric conversion efficiency of the thin film solar cell 10, as shown in FIG. 1.

Refer again to FIG. 1, wherein, the lower electrode layer 130 is provided on the photovoltaic layer 120, and the lower electrode layer 130 is provided with adjustable and designable patterns. Herein, pattern is referred to as trademark pattern, logo pattern, or company name. Yet in other embodiments, decorative patterns, drawings, commodity identification codes that are esthetically pleasing can also be designed on the lower electrode layer 130, so as to achieve the objective of esthetically pleasing, sales promotion, and theft prevention, however, the present invention is not limited to this. In the following, two embodiments are described, such that patterns can be provided on lower electrode layer 130. In one embodiment, a thin film pattern layer 140 is disposed between a conductive layer and a transparent substrate 150, hereby forming a lower electrode layer 130 as shown in FIG. 1. In another embodiment, metals of a plurality of colors are utilized to make the lower electrode layer 130 as shown in FIG. 2, so that in addition to the electrode conduction function, the lower electrode layer 130 is also provided with various patterns. But it is worth mentioning that, the embodiments mentioned above are only a few of a plurality of embodiments, the present invention should not be restricted to the ways that the lower electrode layer 130 having its patterns.

In the thin film solar cell 10, the lower electrode layer 130 includes a conductive layer 135 and thin film pattern layer 140. For the lower electrode layer 130, the thin film pattern layer 140 can be classified into a plurality of color regions based on the patterns provided by the designers, and thin film pattern layer of the same color region are applied with metal of the same color, and that can be designed and adjusted based on patterns desired by the designer. In the present invention, metals having colors can be Ni, Ag, Au, or Al, so as to make thin film pattern layer 140 to display various colors, such as colors of gold, silver, purple, tawny, etc., for combining them into patterns required by the user. In addition, in the present embodiment, the conductive layer 135 is disposed between photovoltaic layer 120 and thin film pattern layer 140, for enabling the lower electrode layer 130 to have functions of an electrode. In the present embodiment, the conductive layer 135 is a transparent conductive layer, so that viewers looking from the transparent substrate 100 to the thin film solar cell 10, or from the transparent substrate 150 to the thin film solar cell 10 is able to see clearly the patterns on the thin film pattern layer 140, so as to achieve the objective of esthetically pleasing and sales promotion. However, in other embodiments, the conductive layer 135 may not be a transparent conductive layer, so that viewers looking from the transparent substrate 100 to the thin film solar cell 10, is not able to see the patterns on the thin film pattern layer 140, thus patterns on the thin film pattern layer 140 can only be seen when looking from transparent substrate 150 to the thin film solar cell 10. In this way, pattern information (such as product identification code) can be placed in the lower electrode layer 130 of the thin film solar cell 10, such that even when the solar cell is stolen, it is possible to identify owner of the solar cell, in achieving theft prevention function of the present invention.

Refer again to FIG. 1, wherein, a substrate 150 is provided in order to glue and protect the thin film solar cell 10. In the present embodiment, the substrate 150 can be a transparent substrate; however, in other embodiment, the substrate 150 can be a reflective substrate, yet it must display the patterns on the lower electrode layer 130. Nevertheless, substrate 150 is not a keypoint of the present embodiment, thus the present invention is not limited to this.

Then, refer to FIG. 2 for a cross section view of thin film solar cell having adjustable or designable patterns according to another embodiment of the present invention. The present embodiment is similar to the previous one, and the only difference is that the lower electrode 130 of the thin film solar cell 20 is not provided with a thin film pattern layer 140, so that the lower electrode 130 can be divided into a plurality of color regions based on the patterns desired by the users, and the lower electrode layer 130 of the same color region is applied with metal of the same color, so as to form patterns, hereby making the lower electrode layer 130 have the same function of conductive electrode.

Moreover, in the present embodiment, the thin film solar cell 20 further includes a temperature dependent optical layer 160, disposed between a photovoltaic layer 120 and a lower electrode layer 130, so that the transmittance of the thin film solar cell 20 for the infrared light can be varied automatically based on the present temperature T. For example, when the temperature is excessively high, then the transmittance of the thin film solar cell 20 for the infrared light will be lowered, so as to increase the ratio of infrared light that is blocked from passing through the thin film solar cell 20. As such, in case that a building is made by using the thin film solar cell 20 of the present Embodiment, then the temperature inside the building can be avoided to be excessively high, when the temperature outside the building is high. In contrast, when the temperature outside the building is low, then the transmittance of the thin film solar cell 20 for the infrared light will be increased, so that more infrared light in the incident light L can pass through, as such, in case that a building is made by using the thin film solar cell 20 of the present Embodiment, then the temperature inside the building can more easily be increased. In the present Embodiment, the temperature dependent optical layer 160 is made of vanadium dioxide, or a compound of oxygen and vanadium.

It has to be mentioned that, in an embodiment, the thin film solar cell 10 can also be provided with the temperature dependent optical layer (not shown) mentioned above, and it likewise can also have the advantages of the thin film solar cell 20, thus it will not be repeated here for brevity.

Summing up the above, in an embodiment of the present invention, the lower electrode layer is provided with adjustable or designable patterns, such that the operations of the photovoltaic layer can be sustained by means of the sunlight incident through the transparent substrate, thus users may view and appreciate the various patterns in the thin film solar cell. In this respect, product identification codes can be embedded into the lower electrode layer of the thin film solar cell, so as to realize the objective of esthetical appearance, brand identification, sales promotion, and theft prevention. Moreover, in another embodiment of the present invention, a temperature dependent optical layer can be provided, so that the transmittance of the thin film solar cell for the infrared light in the sunlight can be adjusted based on the temperature, so as to control the lighting and temperature of a building, hereby lowering the air conditioner utilization rate, and reducing expense on electricity.

Moreover, in addition to being applicable to window or roof of a building for esthetics and sales promotion purpose, the thin film solar cell having adjustable or designable patterns can also be applicable to a plant or flower cultivating industry requiring much more green light or mixture of blue light and green light. In order words, the intelligent thin film solar cell of the present invention is able to make great contributions to various Industries.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A thin film solar cell having adjustable or designable patterns, comprising:
a transparent substrate;
an upper electrode layer, disposed on said transparent substrate, said upper electrode layer is a transparent electrode;
a photovoltaic layer, disposed on said upper electrode layer; and
a lower electrode layer, disposed on said photovoltaic layer, and having said adjustable or designable patterns.

2. The thin film solar cell having adjustable or designable patterns as claimed in claim 1, wherein said lower electrode further includes a conductive layer and a thin film pattern layer, and said thin film pattern layer is provided with said adjustable and designable patterns.

3. The thin film solar cell having adjustable or designable patterns as claimed in claim 2, wherein said conductive layer is disposed between said photovoltaic layer and said thin film pattern layer.

4. The thin film solar cell having adjustable or designable patterns as claimed in claim 2, wherein said conductive layer is a transparent conductive layer.

5. The thin film solar cell having adjustable or designable patterns as claimed in claim 2, wherein said thin film pattern layer is divided into a plurality of color regions according to said patterns, and said color regions of a same color of said thin film pattern layer are applied metal of a color.

6. The thin film solar cell having adjustable or designable patterns as claimed in claim 1, wherein said lower electrode layer is divided into said plurality of color regions according to said patterns, and said color regions of said same color of said lower electrode layer are applied metal of a color.

7. The thin film solar cell having adjustable or designable patterns as claimed in claim 1, wherein said pattern is a trademark pattern, a logo pattern, or a company name.

8. The thin film solar cell having adjustable or designable patterns as claimed in claim 1, further comprising: a temperature dependent optical layer, disposed between said photovoltaic layer and said lower electrode layer, transmittance of said temperature dependent optical layer to infrared light is varied depending on its temperature, and when temperature of said temperature dependent optical layer increases to a specific range, transmittance of said temperature dependent optical layer to said infrared light is reduced.

9. The thin film solar cell having adjustable or designable patterns as claimed in claim 8, wherein said temperature dependent optical layer is made of vanadium dioxide.

10. The thin film solar cell having adjustable or designable patterns as claimed in claim 1, wherein said photovoltaic layer includes an N-type semiconductor layer and a P-type semiconductor layer, disposed sequentially between said upper electrode layer and said lower electrode layer.
